(19) United States
(12) Patent Application Publication
(10) Pub. No.: US 2010/0308308 A1
(43) Pub. Date: Dec. 9, 2010

(54) USE OF SUBSTITUTED TRIS(DIPHENYLAMINO)TRIAZINE COMPOUNDS IN OLEDS

(75) Inventors: Evelyn Fuchs, Mannheim (DE); Nicolle Langer, Heppenheim (DE); Christian Lennartz, Schifferstadt (DE); Peter Strohriegl, Bayreuth (DE); Michael Rothmann, Bayreuth (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, Ludwigshafen (DE)

(21) Appl. No.: 12/739,523

(22) PCT Filed: Oct. 15, 2008
(86) PCT No.: PCT/EP2008/063814

§ 371 Date: Apr. 23, 2010

(30) Foreign Application Priority Data
Oct. 24, 2007 (EP) 07119144.9

(51) Int. Cl. H01L 51/54

(52) U.S. Cl. 257/40; 257/E51.041

(57) ABSTRACT

The present invention relates to an organic light-emitting diode comprising at least one tris(diphenylamino)triazine compound with at least one alkoxy or aryloxy radical, to a light-emitting layer comprising at least one tris(diphenylamino)triazine compound with at least one alkoxy or aryloxy radical, to the use of the aforementioned compounds as a matrix material, hole/exciton blocker material, electron/exciton blocker material, hole injection material, electron injection material, hole conductor material and/or electron conductor material, and to a device selected from the group consisting of stationary visual display units, mobile visual display units and illumination units comprising at least one inventive organic light-emitting diode.

The present invention relates to an organic light-emitting diode comprising at least one tris(diphenylamino)triazine compound with at least one alkoxy or aryloxy radical, to a light-emitting layer comprising at least one tris(diphenylamino)triazine compound with at least one alkoxy or aryloxy radical, to the use of the aforementioned compounds as a matrix material, hole/exciton blocker material, electron/exciton blocker material, hole injection material, electron injection material, hole conductor material and/or electron conductor material, and to a device selected from the group consisting of stationary visual display units, mobile visual display units and illumination units comprising at least one inventive organic light-emitting diode.

Organic light-emitting diodes (OLEDs) exploit the property of materials of emitting light when they are excited by electrical current. OLEDs are of particular interest as an alternative to cathode ray tubes and to liquid-crystal displays for producing flat visual display units. Owing to the very compact design and the intrinsically low power consumption, devices comprising OLEDs are suitable especially for mobile applications, for example for applications in cellphones, laptops, etc., and for illumination.

The basic principles of the way in which OLEDs work and suitable structures (layers) of OLEDs are known to those skilled in the art and are specified, for example, in WO 2005/113704 and the literature cited therein. The light-emitting materials (emitters) used may, as well as fluorescent materials (fluorescence emitters), be phosphorescent materials (phosphorescence emitters). The phosphorescence emitters are typically organometallic complexes which, in contrast to the fluorescence emitters which exhibit singlet emission, exhibit triplet emission (triplet emitters) (M. A. Baldow et al., Appl. Phys. Lett. 1999, 75, 4 to 6). For quantum-mechanical reasons, when the triplet emitters (phosphorescence emitters) are used, up to four times the quantum efficiency, energy efficiency and power efficiency is possible. In order to implement the advantages of the use of the organometallic triplet emitters (phosphorescence emitters) in practice, it is necessary to provide device compositions which have a high operative lifetime, a good efficiency, a high stability to thermal stress and a low use and operating voltage.

Such device compositions may, for example, comprise specific matrix materials in which the actual light emitter is present in distributed form. In addition, the compositions may comprise blocker materials, it being possible for hole blockers, exciton blockers and/or electron blockers to be present in the device compositions. Additionally or alternatively, the device compositions may further comprise hole injection materials and/or electron injection materials and/or hole conductor materials and/or electron conductor materials. The selection of the aforementioned materials which are used in combination with the actual light emitter has a significant influence on parameters including the efficiency and the lifetime of the OLEDs.

The prior art proposes numerous different materials for use in OLEDs. Among the proposed materials are also those which comprise tris(diphenylamino)triazine compounds.

EP 1 701 394 A1 discloses OLEDs which have a light-emitting layer which is formed from a matrix polymer and two or more phosphorescent host materials and at least one phosphorescent dopant material. The phosphorescent host materials may be triazine compounds. Suitable triazine compounds mentioned are 2,4,6-tris(diarylamino)-1,3,5-triazine, 2,4,6-tris(diphenylamino)-1,3,5-triazine, 2,4,6-tricarbazolo-1,3,5-triazine, 2,4,6-tris(N-phenyl-2-naphthylamino)-1,3,5-triazine, 2,4,6-tris(N-phenyl-1-naphthylamino)-1,3,5-triazine and 2,4,6-trisbiphenyl-1,3,5-triazine.

EP 1 610 398 A2 discloses OLEDs which have a light-emitting layer and which are formed from a dopant material and a host material. The host material comprises at least one hole transport compound and at least one compound which may be a triazine compound. Suitable triazine compounds mentioned are 2,4,6-tris(diarylamino)-1,3,5-triazine, 2,4,6-tris(diphenylamino)-1,3,5-triazine, 2,4,6-tricarbazolo-1,3,5-triazine, 2,4,6-tris(N-phenyl-2-naphthylamino)-1,3,5-triazine, 2,4,6-tris(N-phenyl-1-naphthylamino)-1,3,5-triazine and 2,4,6-trisbiphenyl-1,3,5-triazine.

JP 10-302960 A relates to luminescent materials for OLEDs, which may be triazines among other compounds.

J. C. Li et al., Chem. Mater. 2004, 16, 4711-4714 relates to a study of three different types of amines (phenylenediamine, benzidines and dendritic arylamines) with regard to their suitability as hole transport materials in OLEDs. One example relates to methoxy-substituted tris(diphenylamino)triazine compounds where the methoxy groups are arranged in the para position. The example cited is not shown to be advantageous compared to the other examples cited.

U.S. Pat. No. 5,716,722 discloses OLEDs which, as a hole transport material, comprise a compound with a triazine ring with at least one directly bonded diphenylamino group. According to U.S. Pat. No. 5,716,722, hole transport materials are to be provided, which are difficult to crystallize, since crystallization in the hole transport layer can lead to short circuits, such that no light is emitted in the crystallized regions.

V. Vaitkeviciene et al., Mol. Cryst. Liq. Cryst., Vol. 468, pp. 141/[493]-150/[502], 2007 relates to aromatic amines which are based on triazine and are suitable as charge transport materials. A symmetrical tris(ditolylamino)-substituted triazine is compared to unsymmetrical 6-phenyl-1,3,5-triazine. A high thermal stability is found for the unsymmetrical triazine. Moreover, the unsymmetrical triazine is a material which is amorphous within the temperature range from 0 to 300° C., while the symmetrical triazine crystallizes. According to V. Vaitkeviciene et al., the unsymmetrical triazine constitutes a potential charge transport material for electroluminescent elements. V. Vaitkeviciene et al., however, does not comprise an example in which the suitability of the unsymmetrical triazine as a charge transport material in electroluminescent elements is shown. Moreover, V. Vaitkeviciene et al. does not comprise any information relating to an extension of the lifetime of OLEDs when the unsymmetrical triazine is used.

It is an object of the present invention to provide materials which are suitable for use in OLEDs, especially for use as a matrix material, especially as a matrix material in the light-emitting layer, hole/exciton blocker material, electron/exciton blocker material, hole injection material, electron injection material, hole conductor material and/or electron conductor material, which have amorphous properties improved over the materials specified in the prior art, i.e. have a reduced crystallization tendency, and also to provide OLEDs with an improved property profile which is manifested in an improved performance, for example a prolonged lifetime, good luminances, high quantum yields, etc.

This object is achieved by an organic light-emitting diode comprising at least one tris(diphenylamino)triazine compound of the general formula (I)

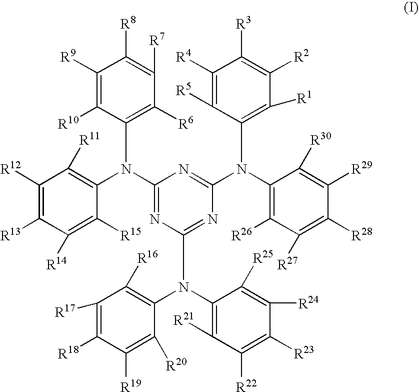

in which the R¹ to R³⁹ radicals are each independently defined as follows:
hydrogen, alkyl, cycloalkyl, heterocycloalkyl, aryl, heteroaryl, OH, O-alkyl, O-aryl, O-heteroaryl, SH, S-alkyl, S-aryl, halogen, pseudohalogen, amino or further substituents with donor or acceptor action,
or
a radical of the formula (I)

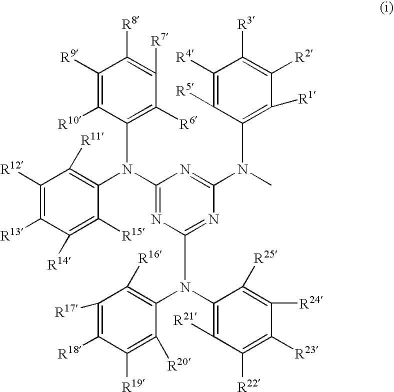

in which the R^{1′}, R^{2′}, R^{3′}, R^{4′}, R^{5′}, R^{6′}, R^{7′}, R^{8′}, R^{9′}, R^{10′}, R^{11′}, R^{12′}, R^{13′}, R^{14′}, R^{15′}, R^{16′}, R^{17′}, R^{18′}, R^{19′}, R^{20′}, R^{21′}, R^{22′}, R^{23′}, R²⁴ and R^{25′} radicals are each independently as defined for the R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴ and R²⁵ radicals;
with the condition that at least one of the radicals of at least one of the R², R⁴, R⁷, R⁹, R¹², R¹⁴, R¹⁷, R¹⁹, R²², R²⁴, R²⁷ or R²⁹ radicals is O-alkyl or O-aryl, preferably O-alkyl.

The compounds of the formula I thus have at least one alkyloxy or aryloxy radical, preferably at least one alkyloxy radical, in the m position to the bonding site of the phenyl groups joined to the nitrogen atom of the diphenylamino groups. It has been found that compounds of the formula I which have one or more substituents in the m position are notable for a particularly low crystallization tendency.

The expression “further substituents with donor or acceptor action” is understood to mean the substituents with donor or acceptor action which are specified below but have not already been specified explicitly in the definition of the R¹ to R³⁹ radicals.

The present invention thus relates to specifically substituted tris(diphenylamino)triazine compounds which have at least one alkoxy or aryloxy radical. It has been found that these compounds are notable for a particularly low crystallization tendency and are particularly suitable for use in OLEDs.

Depending on their substitution pattern, the compounds of the formula (I) can be used as a matrix, especially as a matrix in the light-emitting layer, as a hole/exciton blocker, as an electron/exciton blocker, as hole injection materials, as electron injection materials, as a hole conductor and/or as an electron conductor. Corresponding layers of OLEDs are known to those skilled in the art and are specified, for example, in WO 2005/113704 or WO 2005/019373.

Alkyl is understood to mean substituted or unsubstituted C₁-C₂₀-alkyl radicals. Preference is given to C₁- to C₁₋₁₀-alkyl radicals, particular preference to C₁- to C₆-alkyl radicals. The alkyl radicals may be either straight-chain or branched. In addition, the alkyl radicals may be substituted by one or more substituents selected from the group consisting of C₁-C₂₀-alkoxy, halogen, preferably F, and C₆-C₃₀-aryl which may in turn be substituted or unsubstituted. Suitable aryl substituents and suitable alkoxy and halogen substituents are specified below. Examples of suitable alkyl groups are methyl, ethyl, propyl, butyl, pentyl, hexyl, heptyl and octyl, and also derivatives of the alkyl groups mentioned substituted by C₈-C₃₀-aryl, C₁-C₂₀-alkoxy and/or halogen, especially F, for example CF₃. This also comprises both the n-isomers of the radicals mentioned and branched isomers such as isopropyl, isobutyl, isopentyl, sec-butyl, tert-butyl, neopentyl, 3,3-dimethylbutyl, 3-ethylhexyl, etc. Preferred alkyl groups are methyl, ethyl, tert-butyl and CF₃.

Cycloalkyl is understood to mean substituted or unsubstituted C₃-C₂₀-alkyl radicals. Preference is given to C₃- to C₁₀-alkyl radicals, particular preference to C₃- to C₈-alkyl radicals. The cycloalkyl radicals may bear one or more of the substituents mentioned for the alkyl radicals. Examples of suitable cyclic alkyl groups (cycloalkyl radicals), which may likewise be unsubstituted or substituted by the radicals mentioned above for the alkyl groups, are cyclopropyl, cyclobutyl, cyclopentyl, cyclohexyl, cycloheptyl, cyclooctyl, cyclononyl and cyclodecyl. If appropriate, cycloalkyl may also be polycyclic ring systems such as decalinyl, norbornyl, bornanyl or adamantyl.

Suitable O-alkyl and S-alkyl groups are C₁-C₂₀-alkoxy and C₁-C₂₀-alkylthio groups, and derive correspondingly from the aforementioned C₁-C₂₀-alkyl radicals. Examples here include OCH₃, OC₂H₅, OC₃H₇, OC₄H₉ and OC₈H₁₇, and also SCH₃, SC₂H₅, SC₃H₇, SC₄H₉ and SC₈H₁₇. C₃H₇, C₄H₉ and C₈H₁₇ comprise both the n-isomers and branched isomers such as isopropyl, isobutyl, sec-butyl, tert-butyl and 2-ethylhexyl. Particularly preferred alkoxy or alkylthio groups are methoxy, ethoxy, n-octyloxy, 2-ethylhexyloxy and SCH₃.

Suitable halogen radicals or halogen substituents in the context of the present application are fluorine, chlorine, bromine and iodine, preferably fluorine, chlorine and bromine, more preferably fluorine and chlorine, most preferably fluorine.

Suitable pseudohalogen radicals in the context of the present application are CN, SCN, OCN, N₃ and SeCN, preference being given to CN and SCN. Very particular preference is given to CN.

Suitable aryl radicals are C₆-C₃₀-aryl radicals which are derived from monocyclic, bicyclic or tricyclic aromatics which do not comprise any ring heteroatoms. When the system is not a monocyclic system, the saturated form (perhydro form) or the partly unsaturated form (for example the dihydro form or tetrahydro form) are also possible for the second ring in the case of the designation “aryl”, provided that the particular forms are known and stable. In other words, the term “aryl” in the present invention also comprises, for example, bicyclic or tricyclic radicals in which either both or all three radicals are aromatic, and also bicyclic or tricyclic radicals in which only one ring is aromatic, and also tricyclic radicals in which two rings are aromatic. Examples of aryl are: phenyl, naphthyl, indanyl, 1,2-dihydronaphthenyl, 1,4-dihydronaphthenyl, indenyl, anthracenyl, phenanthrenyl or 1,2,3,4-tetrahydronaphthyl. Particular preference is given to C₆-C₁₀-aryl radicals, for example phenyl or naphthyl, very particular preference to C₆-aryl radicals, for example phenyl.

The aryl radicals may be unsubstituted or substituted by one or more further radicals. Suitable further radicals are selected from the group consisting of C₁-C₂₀-alkyl, C₆-C₃₀-aryl or substituents with donor or acceptor action, suitable substituents with donor or acceptor action being specified below. The C₆-C₃₀-aryl radicals are preferably unsubstituted or substituted by one or more C₁-C₂₀-alkoxy groups, CN, CF₃, F or amino groups. Further preferred substitutions of the C₆-C₃₀-aryl radicals depend on the end use of the compounds of the general formula (I) and are specified below.

Suitable O-aryl and S-aryl radicals are C₆-C₃₀-aryloxy, C₆-C₃₀-alkylthio radicals, and derive correspondingly from the aforementioned C₆-C₃₀-aryl radicals. Particular preference is given to phenoxy and phenylthio.

Heteroaryl is understood to mean unsubstituted or substituted heteroaryl radicals which have from 5 to 30 ring atoms, may be monocyclic, bicyclic or tricyclic and derive partly from the aforementioned aryl, in which at least one carbon atom in the aryl base structure has been replaced by a heteroatom. Preferred heteroatoms are N, O and S. The heteroaryl radicals more preferably have from 5 to 13 ring atoms. Especially preferably, the base structure of the heteroaryl radicals is selected from systems such as pyridine and five-membered heteroaromatics such as thiophene, pyrrole, imidazole or furan. These base skeletons may optionally be fused to one or two six-membered aromatic radicals. Suitable fused heteroaromatics are carbazolyl, benzimidazolyl, benzofuryl, dibenzofuryl or dibenzothiophenyl. The base skeleton may be substituted at one, more than one or all substitutable positions, suitable substituents being the same as have already been specified under the definition of C₆-C₃₀-aryl. However, the heteroaryl radicals are preferably unsubstituted. Suitable heteroaryl radicals are, for example, pyridin-2-yl, pyridin-3-yl, pyridin-4-yl, thiophen-2-yl, thiophen-3-yl, pyrrol-2-yl, pyrrol-3-yl, furan-2-yl, furan-3-yl and imidazol-2-yl, and also the corresponding benzofused radicals, especially carbazolyl, benzimidazolyl, benzofuryl, dibenzofuryl or dibenzothiophenyl.

Amino groups are understood to mean radicals of the general formula —NR³¹R³², suitable R³¹ and R³² radicals being specified below. Examples of suitable amino groups are diarylamino groups such as diphenylamino and dialkylamino groups such as dimethylamino, diethylamino, and arylalkylamino groups such as phenylmethylamino.

In the context of the present application, groups/substituents with donor or acceptor action are understood to mean the following groups:

C₁-C₂₀-alkoxy, C₆-C₃₀-aryloxy, C₁-C₂₀-alkylthio, C₆-C₃₀-arylthio, SiR³¹R³²R³³, halogen radicals, halogenated C₁-C₂₀-alkyl radicals, carbonyl (—CO(R³¹)), carbonylthio (—C═O (SR³¹)), carbonyloxy (—C═O(OR³¹)), oxycarbonyl (—OC ═O(R³¹)), thiocarbonyl (—SC═O(R³¹)), amino (—NR³¹R³²), OH, pseudohalogen radicals, amido (—C═O(NR³¹)), —NR³¹C═O(R³²), phosphonate (—P(O)(OR³¹)₂, phosphate (—OP(O)(OR³¹)₂), phosphine (—PR³¹R³²), phosphine oxide (—P(O)R³¹₂), sulfate (—OS(O)₂OR³¹), sulfoxide (S(O)R³¹), sulfonate (—S(O)₂OR³¹), sulfonyl (—S(O)₂R³¹), sulfonamide (—S(O)₂NR³¹R³²), NO₂, boronic esters (—OB(OR³¹)₂), imino (—C═NR³¹R³²)), borane radicals, stannane radicals, hydrazine radicals, hydrazone radicals, oxime radicals, nitroso groups, diazo groups, vinyl groups, (=sulfonate) and boronic acid groups, sulfoximines, alanes, germanes, boroximes and borazines.

Preferred substituents with donor or acceptor action are selected from the group consisting of:

C₁- to C₂₀-alkoxy, preferably C₁-C₆-alkoxy, more preferably ethoxy or methoxy; C₆-C₃₀-aryloxy, preferably C₆-C₁₀-aryloxy, more preferably phenyloxy; SiR³¹R³²R³³ where R³¹, R³² and R³³ are preferably each independently substituted or unsubstituted alkyl or substituted or unsubstituted phenyl, suitable substituents having been specified above, where SiR³¹R³²R³³ is, for example, SiMe₃; halogen radicals, preferably F, Cl, Br, more preferably F or Cl, most preferably F, halogenated C₁-C₂₀-alkyl radicals, preferably halogenated C₁-C₈-alkyl radicals, most preferably fluorinated C₁-C₈-alkyl radicals, e.g. CF₃, CH₂F, CHF₂ or C₂F₅; amino, preferably dimethylamino, diethylamino or diphenylamino; OH, pseudohalogen radicals, preferably CN, SCN or OCN, more preferably CN, —C(O)OC₁-C₄-alkyl, preferably —C(O)OMe, P(O)R₂, preferably P(O)Ph₂, or SO₂R₂, preferably SO₂Ph.

Very particularly preferred substituents with donor or acceptor action are selected from the group consisting of methoxy, phenyloxy, halogenated C₁-C₄-alkyl, preferably CF₃, CH₂F, CHF₂, C₂F₅, halogen, preferably F, CN, SiR³¹R³²R³³, where suitable R³¹, R³² and R³³ radicals have already been mentioned, diphenylamino, —C(O)OC₁-C₄-alkyl, preferably —C(O)OMe, P(O)Ph₂, SO₂Ph.

The aforementioned groups with donor or acceptor action are not intended to rule out the possibility that further aforementioned radicals and groups may also have donor or acceptor action. For example, the aforementioned heteroaryl groups are likewise groups with donor or acceptor action, and the C₁-C₂₀-alkyl radicals are groups with donor action.

The R³¹, R³² and R³³ radicals mentioned in the aforementioned groups with donor or acceptor action are each as already defined above, i.e. R³¹, R³², R³³ are each independently:

substituted or unsubstituted C₁-C₂₀-alkyl or substituted or unsubstituted C₆-C₃₀-aryl, suitable and preferred alkyl and aryl radicals having been specified above. More preferably, the R³¹, R³² and R³³ radicals are C₁-C₆-alkyl, e.g. methyl, ethyl or i-propyl, or substituted or unsubstituted phenyl.

O-Alkyl radicals suitable with preference in the compounds of the formula I are O—C₁— to -C₈-alkyl radicals, preferably methoxy, ethoxy, n-propyloxy, isopropyloxy, n-butyloxy, isobutyloxy, sec-butyloxy, tert-butyloxy radicals, more preferably methoxy or ethoxy radicals, most preferably methoxy radicals.

O-Aryl radicals suitable with preference in the compounds of the formula I are O—C₈— to -C₂₀-aryl radicals, preferably phenyloxy and naphthyloxy radicals, more preferably phenyloxy radicals, which may optionally be substituted by C₁- to C₈-alkyl radicals. Particular preference is given to unsubstituted phenyloxy, 4-alkylphenyloxy and 2,4,6-trialkylphenyloxy.

The further R¹ to R³⁰ radicals are each independently defined as follows: hydrogen, alkyl, cycloalkyl, heterocycloalkyl, aryl, heteroaryl, OH, O-alkyl, O-aryl, O-heteroaryl, SH, S-alkyl, S-aryl, pseudohalogen, halogen, amino or further substituents with donor or acceptor action, or

a radical of the formula (i)

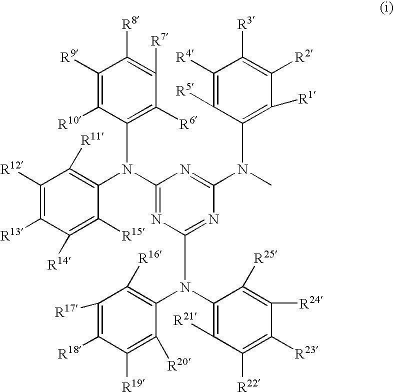

in which the R^{1′}, R^{2′}, R^{3′}, R^{4′}, R^{5′}, R^{6′}, R^{7′}, R^{8′}, R^{9′}, R^{10′}, R^{11′}, R^{12′}, R^{13′}, R^{14′}, R^{15′}, R^{16′}, R^{17′}, R^{18′}, R^{19′}, R^{20′}, R^{21′}, R^{22′}, R^{23′}, R^{24′} and R²⁵ radicals are each independently as defined for the R¹, R², R³, R⁴, R⁶, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴ and R²⁵ radicals.

Suitable alkyl, cycloalkyl, heterocycloalkyl, aryl, heteroaryl, OH, O-alkyl, O-aryl, O-heteroaryl, SH, S-alkyl, S-aryl, halogen, pseudohalogen and amino radicals are specified above.

Preferably, the further R¹ to R³⁰ and R^{1′} to R^{25′} radicals are each independently hydrogen, alkyl, cycloalkyl, O-alkyl, O-aryl, aryl, SH, S-alkyl, S-aryl, halogen, pseudohalogen or amino, more preferably hydrogen, C₁- to C₈-alkyl, especially methyl, ethyl, n-propyl, i-propyl, n-butyl, i-butyl, sec-butyl or tert-butyl, or halogen-substituted C₁- to C₈-alkyl, e.g. CF₃, aryl, especially phenyl, halogen, especially F or Cl, pseudohalogen, especially CN, O-alkyl, especially O—C₁- to C₈-alkyl, O-aryl, especially O—C₆-aryl, or SiR³¹R³²R³³ where the R³¹, R³² and R³³ radicals are each C₁-C₆-alkyl, e.g. methyl, ethyl or i-propyl, or substituted or unsubstituted phenyl, especially SiMe₃, most preferably methyl, ethyl, F, CN, CF₃, SiMe₃ or O-methyl.

The compounds of the formula I may have one or more O-alkyl or O-aryl radicals which may be present at any positions in the molecule, at least one O-alkyl or O-aryl radical being in the m position to the bonding site of the phenyl groups joined to the nitrogen atom of the diphenylamino groups. The compounds of the formula I preferably have 1, 2, 3, 4, 5 or 6 O-alkyl and/or O-aryl radicals, more preferably 1, 2 or 3 O-alkyl and/or O-aryl radicals. In a preferred embodiment, the present invention relates to compounds of the formula I in which 1, 2, 3, 4, 5 or 6, preferably 1, 2 or 3, of the R², R⁴, R⁷, R⁹, R¹², R¹⁴, R¹⁷, R¹⁹, R²², R²⁴, R²⁷ or R²⁹ radicals are each O-alkyl and/or O-aryl. Particularly suitable compounds are, for example, compounds of the formula I in which R², R⁷, R¹², R¹⁷, R²² and R²⁷ are each O-alkyl and/or O-aryl, and also compounds of the formula I in which R², R¹² and R²² are each O-alkyl and/or O-aryl.

In a further embodiment of the present invention, the R¹, R⁵, R⁶, R¹⁰, R¹¹, R¹⁵, R¹⁶, R²⁰, R²¹, R²⁵, R²⁶ and R³⁰ radicals are each hydrogen. This means that, in one embodiment of the present invention, the positions in the o position to the bonding site of the phenyl groups joined to the nitrogen atom of the diphenylamino groups are substituted by hydrogen.

The positions in the p position to the bonding site of the phenyl groups joined to the nitrogen atom of the diphenylamino groups, R³, R⁸, R¹³, R¹⁸, R²³ and R²⁸, may each independently be substituted or unsubstituted (“unsubstituted” is understood to mean that the corresponding radicals are hydrogen). Suitable substituents are specified below.

In one embodiment, the compounds of the formula I have the following formulae (Ia), (Ib), (Ic), (Id), (Ie) or (If):

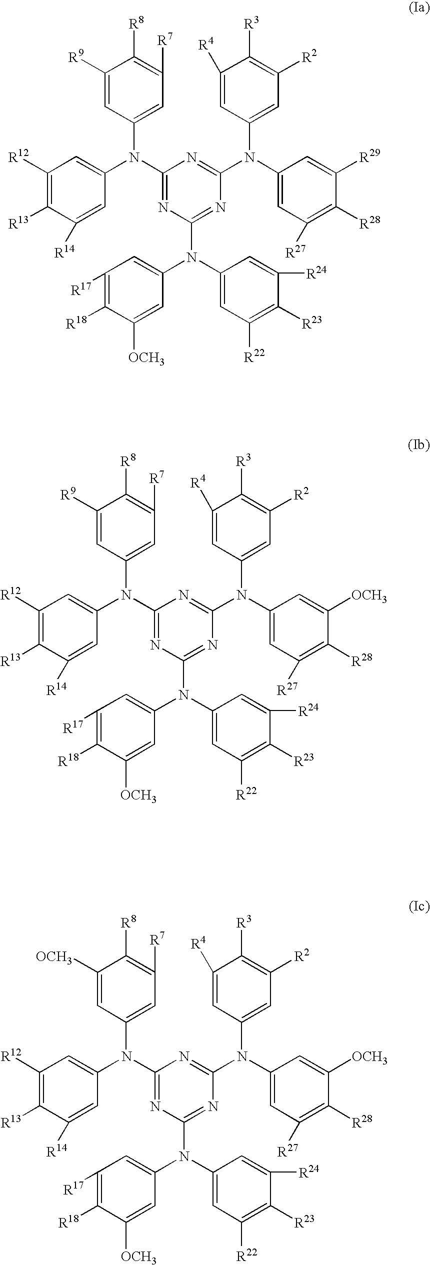

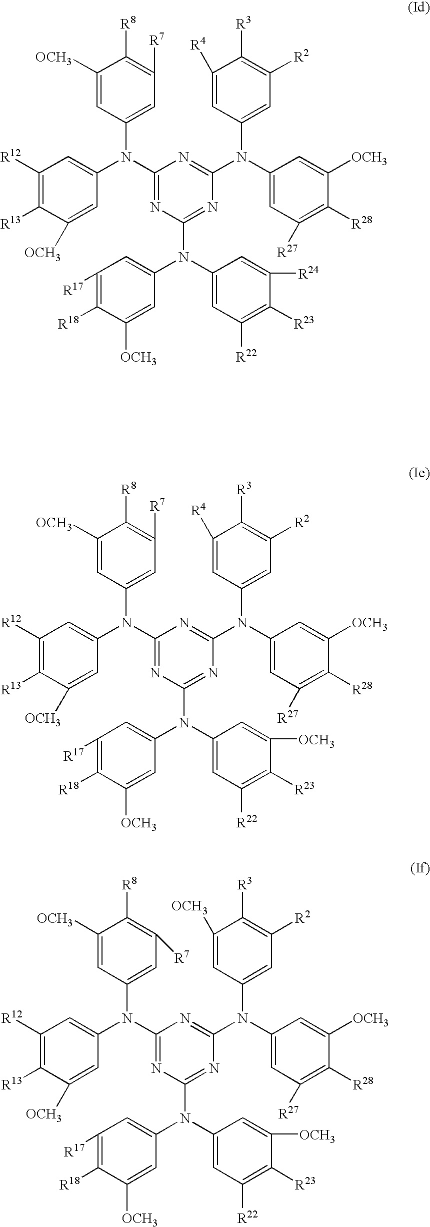

in which R³, R⁸, R¹³, R¹⁸, R²³, and R²⁸ are each independently as defined above. Preferably, R³, R⁸, R¹³, R¹⁸, R²³ and R²⁸ are each independently hydrogen, methyl, ethyl, F, CF₃, SiMe₃ or CN. In a further embodiment, R³, R⁸, R¹³, R¹⁸, R²³ and R²⁸ are preferably each independently methyl, ethyl, F, CF₃, SiMe₃ or CN.

The R², R⁴, R⁷, R⁹, R¹², R¹⁴, R¹⁷, R²², R²⁴, R²⁷ and R²⁹ radicals in the compounds of the formulae Ia, Ib, Ic, Id, Ie and If—if they are not OCH₃—are each independently as defined above. Preferably, R², R⁴, R⁷, R⁹, R¹², R¹⁴, R¹⁷, R²², R²⁴, R²⁷ or R²⁹—if they are not OCH₃—are each hydrogen or C₁- to C₄-alkyl.

The tris(diphenylamino)triazine compounds of the general formula I used in accordance with the invention are prepared by processes known to those skilled in the art, for example by nucleophilic substitution of tris-1,3,5-trichloro-2,4,6-triazine with suitable lithium diarylamides, for example according to the process specified in H. Inomata et al., Chemistry of Materials 2004, 16, 1285. In scheme 1 below, a general reaction scheme for preparing the compounds of the formula I is shown by way of example:

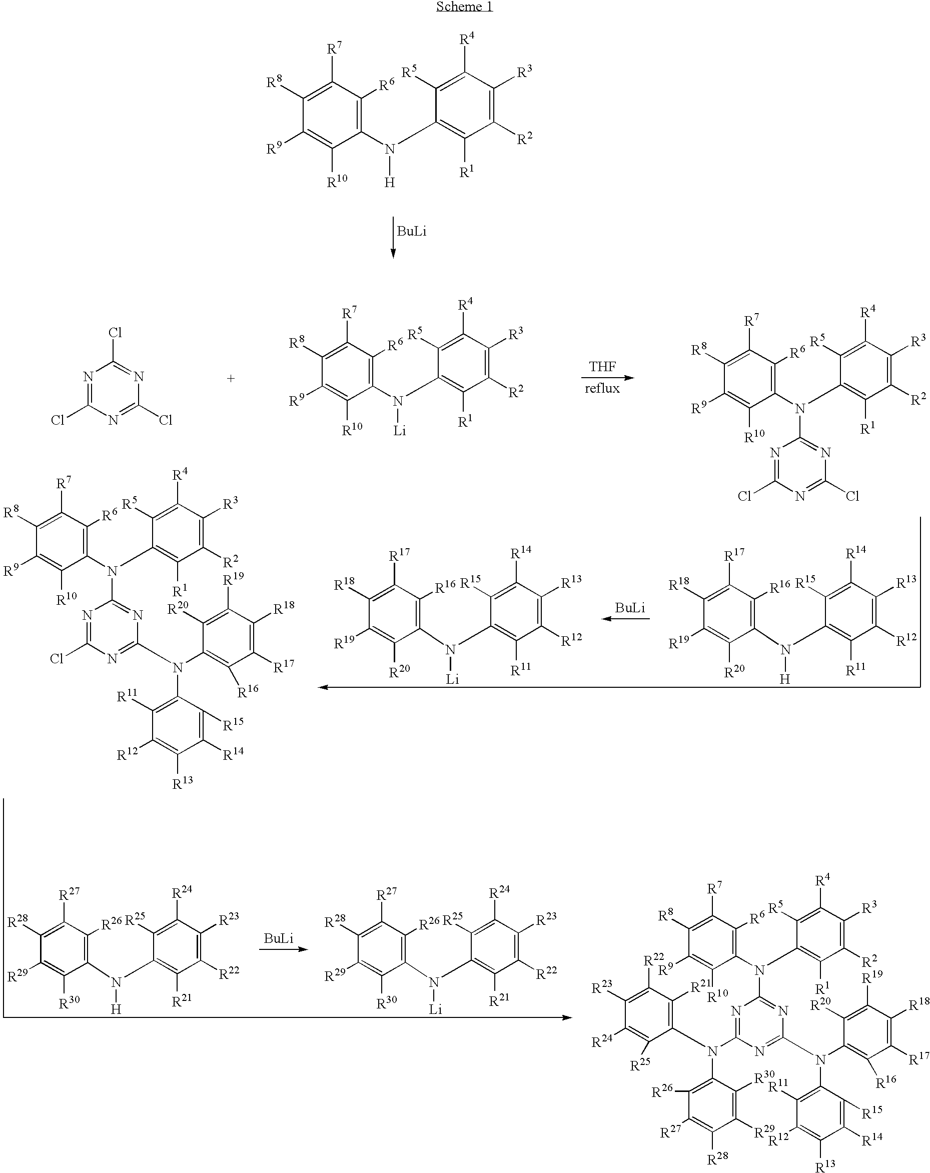

The R¹ to R³⁰ radicals shown in scheme 1 are each as defined above.

The compounds of the formula (I) are outstandingly suitable for use as matrix materials in organic light-emitting diodes. In particular, they are suitable as matrix materials in the light-emitting layer of the OLEDs, in which case the light-emitting layer preferably comprises one or more triplet emitters as emitter compounds.

In addition, the compounds of the formula (I) are suitable as a hole/exciton blocker material, electron/exciton blocker material, hole injection material, electron injection material, hole conductor material and/or electron conductor material, and they are preferably used in the inventive OLED together with at least one triplet emitter.

The function of the compounds of the formula (I) as a matrix material, preferably in the light-emitting layer, as a hole/exciton blocker material, as an electron/exciton blocker material, as a hole injection material, as an electron injection material, as a hole conductor material or as an electron conductor material depends upon factors including the electronic properties of the compounds of the formula (I), i.e. on the substitution pattern of the compounds of the formula (I), and additionally on the electronic properties (relative positions of the HOMOs and LUMOs) of the particular layers used in the inventive OLED. It is thus possible through a suitable substitution of the compounds of the formula (I) to adjust the HOMO and LUMO orbital positions with respect to the further layers used in the inventive OLED, and thus to achieve a high stability of the OLED and hence a long operative lifetime and good efficiencies.

The principles regarding the relative positions of HOMO and LUMO in the individual layers of an OLED are known to those skilled in the art. The principles, by way of example with regard to the properties of the blocking layer for electrons and of the blocking layer for holes, in relation to the light-emitting layer are detailed hereinafter:

The LUMO of the blocking layer for electrons is energetically higher than the LUMO of the materials used in the light-emitting layer (both of the emitter material and of any matrix materials used). The greater the energetic difference of the LUMOs of the blocking layer for electrons and of the materials in the light-emitting layer is, the better are the electron- and/or exciton-blocking properties of the blocking layer for electrons. Suitable substitution patterns of the compounds of the formula (I) suitable as electron and/or exciton blocker materials thus depend upon factors including the electronic properties (especially the position of the LUMO) of the materials used in the light-emitting layer.

The HOMO of the blocking layer for holes is energetically lower than the HOMOs of the materials present in the light-emitting layer (both of the emitter materials and of any matrix materials present). The greater the energetic difference of the HOMOs of the blocking layer for holes and of the materials present in the light-emitting layer is, the better are the hole- and/or exciton-blocking properties of the blocking layer for holes. Suitable substitution patterns of the compounds of the formula (I) suitable as hole and/or exciton blocker materials thus depend upon factors including the electronic properties (especially the position of the HOMOs) of the materials present in the light-emitting layer.

Comparable considerations relating to the relative position of the HOMOs and LUMOs of the different layers used in the inventive OLED apply to the further layers which may be used in the OLED and are known to those skilled in the art.

The energies of the HOMOs and LUMOs of the materials used in the inventive OLED can be determined by different methods, for example by solution electrochemistry, for example cyclic voltammetry. In addition, the position of the LUMO of a particular material can be calculated from the HOMO determined by ultraviolet photon electron spectroscopy (UPS) and the band gap determined optically by absorption spectroscopy.

The present invention therefore further provides for the use of the tris(diphenylamino)-triazine compounds of the formula (I) as a matrix material, preferably as a matrix material in a light-emitting layer of the organic light-emitting diode, and/or as a hole/exciton blocker material, electron/exciton blocker material, hole injection material, electron injection material, hole conductor material and/or electron conductor material, the compounds of the formula (I) preferably being used together with at least one triplet emitter in the organic light-emitting diode.

Preference is given to using the compound of the formula (I), in one embodiment, as a matrix material, the matrix material more preferably being used together with a triplet emitter.

In addition, the compounds of the formula (I) in OLEDs can be used both as a matrix material and as a hole/exciton blocker material, electron/exciton blocker material, hole injection material, electron injection material, hole conductor material and/or electron conductor material. In this case, the matrix material, the hole/exciton blocker material, the electron/exciton blocker material, the hole injection material, the electron injection material, the hole conductor material and/or the electron conductor material may be the same or different compounds of the formula (I).

The present invention further provides a light-emitting layer comprising at least one compound of the formula (I) and at least one emitter compound, the emitter compound preferably being a triplet emitter.

The use of the compounds of the formula (I) as matrix materials in the light-emitting layer of an OLED likewise forms part of the subject-matter of the present invention.

In this context, the use of the compounds of the formula (I) as matrix materials and/or as a hole/exciton blocker material, electron/exciton blocker material, hole injection material, electron injection material, hole conductor material and/or electron conductor material shall not exclude the possibility that these compounds themselves also emit light. The matrix materials and/or hole/exciton blocker materials, electron/exciton blocker materials, hole injection materials, electron injection materials, hole conductor materials and/or electron conductor materials of the formula (I) used in accordance with the invention have a reduced crystallization tendency compared to otherwise customary materials. Using the compounds of the formula (I), it is possible to provide OLEDs with an improved property profile, which is manifested in an improved performance, for example a prolonged lifetime, good luminances, high quantum yields, etc.

The inventive organic light-emitting diodes (OLEDs) are in principle constructed from several layers, for example:

### 1. Anode

2. Hole conductor layer
3. Light-emitting layer
4. Blocking layer for holes/excitons
5. Electron conductor layer

### 6. Cathode

Layer sequences different from the aforementioned construction are also possible, which are known to those skilled in the art. For example, it is possible that the OLED does not have all of the layers mentioned; for example, an OLED comprising layers (1) (anode), (3) (light-emitting layer) and (6) (cathode) is likewise suitable, in which case the functions of the layers (2) (hole conductor layer) and (4) (blocking layer for holes excitons) and (5) (electron conductor layer) are assumed by the adjacent layers. OLEDs which have the layers (1), (2), (3) and (6) or the layers (1), (3), (4), (5) and (6) are likewise suitable. In addition, the OLEDs may have, between the anode (1) and the hole conductor layer (2), a blocking layer for electrons/excitons.

The compounds of the formula I may be used as charge-transporting or -blocking materials. However, they preferably find use as matrix materials in the light-emitting layer.

The compounds of the formula I may be present as the sole matrix material—without further additives—in the light-emitting layer. However, it is likewise possible that, in addition to the compounds of the formula I used in accordance with the invention, further compounds are present in the light-emitting layer. For example, a fluorescent dye may be present in order to modify the emission color of the emitter molecule present. In addition, a dilution material may be used. This dilution material may be a polymer, for example poly(N-vinylcarbazole) or polysilane. However, the dilution material may likewise be a small molecule, for example 4, 4′-N,N′-dicarbazolebiphenyl (CBP=CDP) or tertiary aromatic amines. Where a dilution material is used, the proportion of the compounds of the formula I used in accordance with the invention in the light-emitting layer is generally always still at least 40% by weight, preferably from 50 to 100% by weight, based on the total weight of the compounds of the formula I and diluents.

When at least one compound of the formula (I) is used together with an emitter compound, preferably together with a triplet emitter, in the light-emitting layer of an OLED, which is particularly preferred, the proportion of the at least one compound of the formula (I) in the light-emitting layer is generally from 10 to 99% by weight, preferably from 50 to 99% by weight, more preferably from 70 to 97% by weight. The proportion of the emitter compound in the light-emitting layer is generally from 1 to 90% by weight, preferably from 1 to 50% by weight, more preferably from 3 to 30% by weight, where the proportions of the at least one compound of the formula (I) and of the at least one emitter compound generally add up to 100% by weight. However, it is also possible that the light-emitting layer, as well as the at least one compound of the formula (I) and the at least one emitter compound, comprises further substances, for example further dilution material, suitable dilution material having been specified above.

The individual layers of the OLED among those specified above may in turn be formed from 2 or more layers. For example, the hole-transporting layer may be formed from a layer into which holes are injected from the electrode, and a layer which transports the holes away from the hole-injecting layer into the light-emitting layer. The electron-transporting layer may likewise consist of a plurality of layers, for example a layer in which electrons are injected by the electrode, and a layer which receives electrons from the electron-injecting layer and transports them into the light-emitting layer. These layers mentioned are in each case selected according to factors such as energy level, thermal resistance and charge carrier mobility, and also energy difference of the layers mentioned with the organic layers or the metal electrodes. The person skilled in the art is capable of selecting the construction of the OLEDs such that it is matched optimally to the organic compounds used in accordance with the invention as emitter substances.

In order to obtain particularly efficient OLEDs, the HOMO (highest occupied molecular orbital) of the hole-transporting layer should be matched to the work function of the anode, and the LUMO (lowest unoccupied molecular orbital) of the electron-transporting layer should be matched to the work function of the cathode.

The anode (1) is an electrode which provides positive charge carriers. It may be constructed, for example, from materials which comprise a metal, a mixture of different metals, a metal alloy, a metal oxide or a mixture of different metal oxides. Alternatively, the anode may be a conductive polymer. Suitable metals comprise the metals of groups Ib, IVa, Va and Vla of the Periodic Table of the Elements, and the transition metals of group VIIIa. When the anode is to be transparent, generally mixed metal oxides of groups IIb, IIIb and IVb of the Periodic Table of the Elements (old IUPAC version) are used, for example indium tin oxide (ITO). It is likewise possible that the anode (1) comprises an organic material, for example polyaniline, as described, for example, in Nature, Vol. 357, pages 477 to 479 (Jun. 11, 1992). At least either the anode or the cathode should be at least partly transparent in order to be able to emit the light formed. The material used for the anode (1) is preferably ITO.

Suitable hole conductor materials for layer (2) of the inventive OLEDs are disclosed, for example, in Kirk-Othmer Encyclopedia of Chemical Technology, 4th edition, vol. 18, pages 837 to 860, 1996. Both hole-transporting molecules and polymers can be used as hole transport material. Customarily used hole-transporting molecules are selected from the group consisting of tris[N-(1-naphthyl)-N-(phenylamino)]triphenylamine (1-NaphDATA), 4,4′-bis[N-(1-naphthyl)-N-phenylamino]biphenyl (α-NPD), N,N′-diphenyl-N,N′-bis(3-methylphenyl)-[1,1-b]phenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)N,N′-(3,3′-dimethyl)biphenyl]-4,4′-diamine (ETPD), tetrakis(3-methyl-phenyl)-N,N,N′,N′-2,5-phenylenediamine (PDA), α-phenyl-4-N,N-diphenylaminostyrene (TPS), p-(diethylamino)benzaldehyde diphenyl hydrazone (DEH), triphenylamine (TPA), bis[4-(N,N-diethylamino)-2-methylphenyl)(4-methylphenyl)methane (MPMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), 4,4′,4″-tris(N,N-diphenylamino)tri-phenylamine (TDTA), porphyrin compounds and phthalocyanines such as copper phthalocyanines. Customarily used hole-transporting polymers are selected from the group consisting of polyvinylcarbazoles, (phenylmethyl)polysilanes and polyanilines. It is likewise possible to obtain hole-transporting polymers by doping hole-transporting molecules into polymers such as polystyrene and polycarbonate. Suitable hole-transporting molecules are the molecules already mentioned above.

In addition—in one embodiment—carbene complexes may be used as hole conductor materials, in which case the band gap of the at least one hole conductor material is generally greater than the band gap of the emitter material used. In the context of the present application, band gap is understood to mean the triplet energy. Suitable carbene complexes are, for example, carbene complexes as described in WO 2005/019373 A2, WO 2006/056418 A2 and WO 2005/113704, and in the prior European applications EP 06 112 228.9 and EP 06 112 198.4 which were yet to be published at the priority date of the present application.

The light-emitting layer (3) comprises at least one emitter material. This may in principle be a fluorescence emitter or phosphorescence emitter, suitable emitter materials being known to those skilled in the art. The at least one emitter material is preferably a phosphorescence emitter. The phosphorescence emitter compounds used with preference are based on metal complexes, and especially the complexes of the metals Ru, Rh, Ir, Os, Pd and Pt, in particular the complexes of Ir, have gained significance. The compounds of the formula I used in accordance with the invention are particularly suitable for use together with such metal complexes. In a preferred embodiment, the compounds of the formula (I) are used as matrix materials and/or hole/exciton blocker materials and/or electron/exciton blocker materials. In particular, they are suitable for use as matrix materials and/or hole/exciton blocker materials and/or electron/exciton blocker materials together with complexes of Ru, Rh, Ir, Os, Pd and Pt, more preferably for use together with complexes of Ir.

Suitable metal complexes for use in the inventive OLEDs are described, for example, in documents WO 02/60910 A1, US 2001/0015432 A1, US 2001/0019782 A1, US 2002/0055014 A1, US 2002/0024293 A1, US 2002/0048689 A1, EP 1 191 612 A2, EP 1 191 613 A2, EP 1 211 257 A2, US 2002/0094453 A1, WO 02/02714 A2, WO 00/70655 A2, WO 01/41512 A1, WO 02/15645 A1, WO 2005/019373 A2, WO 2005/113704 A2, WO 2006/115301 A1, WO 2006/067074 A1 and WO 2006/056418.

Further suitable metal complexes are the commercially available metal complexes tris(2-phenylpyridine)iridium(III), tris(2-(4-tolyppyridinato-N,C²′)iridium(III), tris(1-phenyl-isoquinoline)indium(III), bis(2-(2′-benzothienyl)pyridinato-N,C³′)(acetylacetonato)-iridium(III), iridium(III) bis(2-(4,6-difluorophenyl)pyridinato-N,C²)picolinate, iridium(III) bis(1-phenylisoquinoline)(acetylacetonate), iridium(III) bis(di-benzo[f,h]quin-oxaline)(acetylacetonate), iridium(III) bis(2-methyldibenzo[f,h]quinoxaline)(acetyl-acetonate) and tris(3-methyl-1-phenyl-4-trimethylacetyl-5-pyrazoline)terbium(III).

In addition, the following commercially available materials are suitable: tris(dibenzoylacetonato)mono(phenanthroline)europium(III), tris(dibenzoylmethane)-mono(phenanthroline)europium(III), tris(dibenzoylmethane)mono(5-aminophenan-throline)europium(III), tris(di-2-naphthoylmethane)mono(phenanthroline)europium(III), tris(4-bromobenzoylmethane)mono(phenanthroline)europium(III), tris(di(biphenyl-methane))mono(phenanthroline)europium(III), tris(dibenzoylmethane)mono(4,7-diphenylphenanthroline)europium(III), tris(dibenzoylmethane)mono(4,7-dimethyl-phenanthroline)europium(III), tris(dibenzoylmethane)mono(4,7-dimethylphenanthroline-disulfonic acid)europium(III) disodium salt, tris[di(4-(2-(2-ethoxyethoxy)ethoxy)benzoyl-methaneAmono(phenanthroline)europium(III) and tris[d][4-(2-(2-ethoxyethoxy)-ethoxy)benzoylmethane)Jmono(5-aminophenanthroline)europium(III).

Particularly preferred triplet emitters are carbene complexes. In a preferred embodiment of the present invention, the compounds of the formula (I) are used in the light-emitting layer as a matrix material together with carbene complexes as triplet emitters. Suitable carbene complexes are known to those skilled in the art and are specified in some of the aforementioned applications and below. In a further preferred embodiment, the compounds of the formula (I) are used as hole/exciton blocker material together with carbene complexes as triplet emitters. The compounds of the formula (I) may additionally be used both as matrix materials and as hole/exciton blocker materials together with carbene complexes as triplet emitters.

Suitable metal complexes for use together with the compounds of the formula I as matrix materials and/or hole/exciton and/or electron/exciton blocker materials in OLEDs are thus, for example, also carbene complexes as described in WO 2005/019373 A2, WO 2006/056418 A2 and WO 2005/113704, and in the prior European applications EP 06 112 228.9 and EP 06 112 198.4, which were yet to be published at the priority date of the present application. Reference is hereby made explicitly to the disclosure of the WO and EP applications mentioned, and these disclosures shall be incorporated into the content of the present application.

The blocking layer for holes/excitons (4) may comprise hole blocker materials used customarily in OLEDs, such as 2,9-dimethyl-4,7-diphenyl-1,10-phenanthroline (Bathocuproin, (BCP)), bis(2-methyl-8-quinolinato)-4-phenylphenylato)aluminum(III) (BAlq), phenothiazine S,S-dioxide derivatives and 1,3,5-tris(N-phenyl-2-benzylimidazole)benzene) (TPBI), in which case TPBI and BAlq are also suitable as electron-conducting materials. In a further embodiment, compounds which comprise aromatic or heteroaromatic rings bonded via groups comprising carbonyl groups, as disclosed in WO 2006/100298, may be used as blocking layer for holes/excitons (4) or as matrix materials in the light-emitting layer (3).

In a preferred embodiment, the present invention relates to an inventive OLED comprising the layers (1) anode, (2) hole conductor layer, (3) light-emitting layer, (4) blocking layer for holes/excitons, (5) electron conductor layer and (6) cathode, and if appropriate further layers, the blocking layer for holes/excitons comprising at least one compound of the formula (I).

In a further preferred embodiment, the present invention relates to an inventive OLED comprising the layers (1) anode, (2) hole conductor layer, (3) light-emitting layer, (4) blocking layer for holes/excitons, (5) electron conductor layer and (6) cathode, and if appropriate further layers, the light-emitting layer (3) comprising at least one compound of the formula (I) and the blocking layer for holes/excitons comprising at least one compound of the formula (I).

In a further embodiment, the present invention relates to an inventive OLED comprising the layers (1) anode, (2) hole conductor layer and/or (2′) blocking layer for electrons/excitons (the OLED may comprise either layers (2) and (2′), or either layer (2) or layer (2′)), (3) light-emitting layer, (4) blocking layer for holes/excitons, (5) electron conductor layer and (6) cathode, and if appropriate further layers, the blocking layer for electrons/excitons and/or the hole conductor layer and, if appropriate, the light-emitting layer (3) comprising at least one compound of the formula (I).

Suitable electron conductor materials for layer (5) of the inventive OLEDs comprise metals chelated with oxinoid compounds, such as tris(8-quinolinolato)aluminum (Alq₃), bis)2-methyl-8-quinolinato)-4-phenylphenylato)-aluminum(III) (BAlq), compounds based on phenanthroline, such as 2,9-dimethyl-4,7-diphenyl-1,10-phenanthroline (DDPA=BCP) or 4,7-diphenyl-1,10-phenanthroline (DPA), and azole compounds such as 2-(4-biphenylyl)-5-(4-t-butylphenyl)-1,3,4-oxadiazole (PBD) and 3-(4-biphenylyl)-4-phenyl-5-(4-t-butylphenyl)-1,2,4-triazole (TAZ) and 2,2′,2″-(1,3,5-phenylene)tris[1-phenyl-1H-benzimidazole] (TPBI). The layer (5) may serve either to facilitate electron transport or as a buffer layer or as a barrier layer in order to prevent quenching of the exciton at the interfaces of the layers of the OLED. The layer (5) preferably improves the mobility of the electrons and reduces quenching of the exciton. Electron conductor materials suitable with preference are TPBI and BAlq.

Among the materials mentioned above as hole conductor materials and electron conductor materials, some may fulfill several functions. For example, some of the electron-conducting materials are simultaneously hole-blocking materials when they have a low-lying HOMO. These may be used, for example, in the blocking layer for holes/excitons (4). However, it is likewise possible that the function as a hole/exciton blocker is also assumed by layer (5), such that layer (4) can be dispensed with.

The charge transport layers may also be electronically doped in order to improve the transport properties of the materials used, in order firstly to make the layer thicknesses more generous (avoidance of pinholes/short circuits) and in order secondly to minimize the operating voltage of the device. For example, the hole conductor materials may be doped with electron acceptors; for example, it is possible to dope phthalocyanines or arylamines such as TPD or TDTA with tetrafluorotetracyanoquinodimethane (F4-TCNQ). The electron conductor materials may, for example, be doped with alkali metals, for example Alq₃ with lithium. Electronic doping is known to those skilled in the art and is disclosed, for example, in W. Gao, A. Kahn, J. Appl. Phys., Vol. 94, No. 1, Jul. 1, 2003 (p-doped organic layers); A.G. Werner, F. Li, K. Harada, M. Pfeiffer, T. Fritz, K. Leo. Appl. Phys. Lett., Vol. 82, No. 25, Jun. 23, 2003 and Pfeiffer et al., Organic Electronics 2003, 4, 89-103.

The cathode (6) is an electrode which serves to introduce electrons or negative charge carriers. Suitable materials for the cathode are selected from the group consisting of alkali metals of group Ia, for example Li, Cs, alkaline earth metals of group IIa, for example calcium, barium or magnesium, metals of group IIb of the Periodic Table of the Elements (old IUPAC version), comprising the lanthanides and actinides, for example samarium. In addition, it is also possible to use metals such as aluminum or indium, and combinations of all metals mentioned. In addition, lithium-comprising organometallic compounds or LiF may be applied between the organic layer and the cathode in order to reduce the operating voltage.

The OLED according to the present invention may additionally comprise further layers which are known to those skilled in the art. For example, between the layer (2) and the light-emitting layer (3) may be applied a layer which facilitates the transport of the positive charge and/or matches the band gap of the layers to one another. Alternatively, this further layer may serve as a protective layer. In an analogous manner, additional layers may be present between the light-emitting layer (3) and the layer (4) in order to facilitate the transport of the negative charge and/or to match the band gap between the layers to one another. Alternatively, this layer may serve as a protective layer.

In a preferred embodiment, the inventive OLED comprises, in addition to layers (1) to (6), at least one of the further layers specified below:
a hole injection layer between the anode (1) and the hole-transporting layer (2);
a blocking layer for electrons between the hole-transporting layer (2) and the light-emitting layer (3);
an electron injection layer between the electron-transporting layer (5) and the cathode (6).

Those skilled in the art are aware of how suitable materials have to be selected (for example on the basis of electrochemical studies). Suitable materials for the individual layers are known to those skilled in the art and are disclosed, for example, in WO 00/70655.

In addition, it is possible that some or all of the layers used in the inventive OLED are surface-treated in order to increase the efficiency of charge carrier transport. The selection of the materials for each of the layers mentioned is preferably determined so as to obtain an OLED with high efficiency and lifetime.

The inventive OLED can be produced by methods known to those skilled in the art. In general, the inventive OLED is produced by successive vapor deposition of the individual layers onto a suitable substrate. Suitable substrates are, for example, glass, inorganic semiconductors or polymer films. For the vapor deposition, it is possible to use customary techniques such as thermal evaporation, chemical vapor deposition (CVD), physical vapor deposition (PVD) and others. In an alternative process, the organic layers of the OLEDs may be coated from solutions or dispersions in suitable solvents, for which coating techniques known to those skilled in the art are employed.

In general, the different layers have the following thicknesses: anode (1) from 50 to 500 nm, preferably from 100 to 200 nm; hole-conducting layer (2) from 5 to 100 nm, preferably from 20 to 80 nm, light-emitting layer (3) from 1 to 100 nm, preferably from 10 to 80 nm, blocking layer for holes/excitons (4) from 2 to 100 nm, preferably from 5 to 50 nm, electron-conducting layer (5) from 5 to 100 nm, preferably from 20 to 80 nm, cathode (6) from 20 to 1000 nm, preferably from 30 to 500 nm. The relative position of the recombination zone of holes and electrons in the inventive OLED in relation to the cathode and hence the emission spectrum of the OLED can be influenced, inter alia, by the relative thickness of each layer. This means that the thickness of the electron transport layer should preferably be selected such that the position of the recombination zone is matched to the optical resonator property of the diode and hence to the emission wavelength of the emitter. The ratio of the layer thicknesses of the individual layers in the OLED depends on the materials used. The layer thicknesses of any additional layers used are known to those skilled in the art. It is possible that the electron-conducting layer and/or the hole-conducting layer has/have greater thicknesses than the layer thicknesses specified when they are electrically doped.

According to the invention, the light-emitting layer and/or at least one of the further layers optionally present in the inventive OLED comprises at least one compound of the general formula (I). While the at least one compound of the general formula (I) is present in the light-emitting layer as a matrix material, the at least one compound of the general formula (I) can be used in the at least one further layer of the inventive OLED in each case alone or together with at least one of the further aforementioned materials suitable for the corresponding layers. It is likewise possible that the light-emitting layer, as well as the compound of the formula (I), comprises one or more further matrix materials.

The efficiency of the inventive OLEDs can be improved, for example, by optimizing the individual layers. For example, highly efficient cathodes such as Ca or Ba, if appropriate in combination with an intermediate layer of LiF, can be used. Shaped substrates and novel hole-transporting materials which bring about a reduction in the operating voltage or an increase in the quantum efficiency can likewise be used in the inventive OLEDs. In addition, additional layers may be present in the OLEDs in order to adjust the energy level of the different layers and in order to facilitate electroluminescence.

The inventive OLEDs can be used in all devices in which electroluminescence is useful. Suitable devices are preferably selected from stationary and mobile visual display units and illumination units. Stationary visual display units are, for example, visual display units of computers, televisions, visual display units in printers, kitchen appliances and advertising panels, illuminations and information panels. Mobile visual display units are, for example, visual display units in cellphones, laptops, digital cameras, vehicles, and also destination displays on buses and trains.

In addition, the compounds of the formula I can be used in OLEDs with inverse structure. Preference is given to using the compounds of the formula I used in accordance with the invention in these inverse OLEDs, in turn, as matrix materials in the light-emitting layer. The structure of inverse OLEDs and the materials customarily used therein are known to those skilled in the art.

The examples which follow provide additional illustration of the invention.

### EXAMPLES

### 1.) Syntheses of tris(diphenylamino)triazine Compounds

### Example a

### Trisubstitution of 2,4,6-trichloro-1,3,5-triazine (Cyanuric Chloride) to Prepare 2,4,6-tris(diphenylamino)-1,3,5-triazine (1) (Comparative)

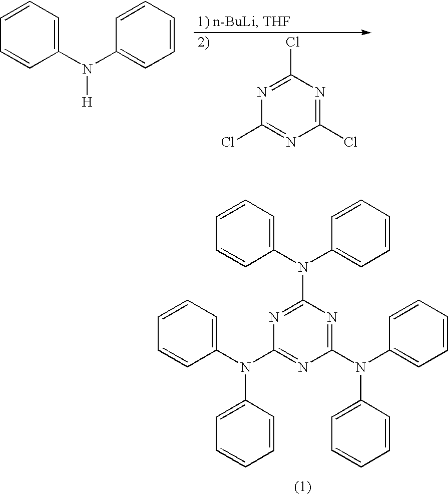

General method A: 5.92 g (35 mmol) of diphenylamine are dissolved in a 250 ml 2-neck flask equipped with a nitrogen inlet and septum in 100 ml of THF dried over potassium under a nitrogen atmosphere. Subsequently, the solution is admixed at room temperature, over a period of 10 minutes, with 21.8 ml (35 mmol) of n-butyllithium (1.6M in hexane) and stirred for a further 10 minutes. In a 500 ml 3-neck flask equipped with a nitrogen inlet, reflux condenser and septum, 1.84 g (10 mmol) of cyanuric chloride are dissolved in 100 ml of THF dried over potassium under a nitrogen atmosphere. The lithium diphenylamide solution is transferred dropwise to the cyanuric chloride solution by means of a transfer cannula. The reaction mixture is subsequently boiled under reflux for 6 hours. After cooling to room temperature, the solvent is evaporated and the residue is stirred in 200 ml of water for 10 minutes. The white solid obtained by filtration is washed with diethyl ether, slurried in hot ethanol and hot-filtered. For further purification, the product is recrystallized in chlorobenzene and dried under high vacuum in order to obtain 3.55 g (61%) of 2,4,6-tris(diphenylamino)-1,3,5-triazine (1) as a white solid.

¹H NMR (250 MHz, CDCl₃) δ (ppm): 7.09-7.16 (m, 24H), 7.02-7.06 (m, 6H).

EI-MS: m/z=582 (M⁺)

### Example b

### Trisubstitution of 2,4,6-trichloro-1,3,5-triazine to prepare 2,4,6-tris(3-methyldiphenylamino)-1,3,5-triazine (2) (Comparative)

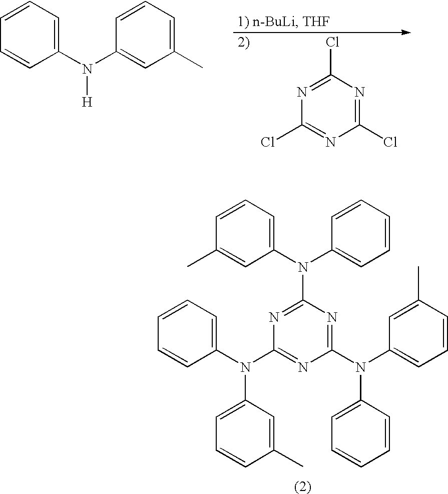

6.41 g (35 mmol) of 3-methyldiphenylamine are reacted with 1.84 g (10 mmol) of cyanuric chloride according to method A and purified to obtain 3.81 g (64%) of 2,4,6-tris(3-methyldiphenylamino)-1,3,5-triazine (2) as a white solid.

¹H NMR (250 MHz, CDCl₃) δ (ppm): 7.08-7.15 (m, 9H), 6.82-7.05 (m, 18H), 2.17 (s, 9H).

EI-MS: m/z=624 (M⁺).

### Example c

### Disubstitution of 2,4,6-trichloro-1,3,5-triazine to prepare 2,4-bis(3-methyldiphenylamino)-6-chloro-1,3,5-triazine (Inventive)

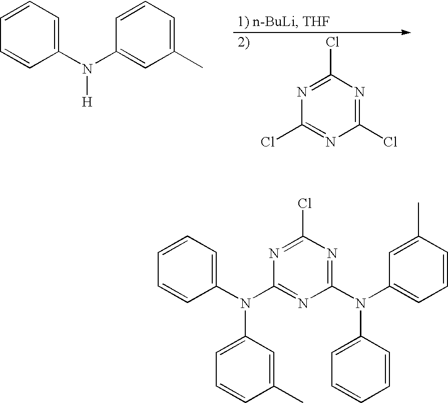

3.66 g (20 mmol) of 3-methyldiphenylamine are reacted with 1.84 g (10 mmol) of cyanuric chloride according to method A. The product is purified by means of column chromatography with a hexane/THF eluent mixture (7/1, V/V) to obtain 3.72 g (78%) of 2,4-bis(3-methyldiphenylamino)-6-chloro-1,3,5-triazine as a white solid.

¹H NMR (250 MHz, CDCl₃) δ (ppm): 7.07-7.16 (m, 6H), 6.81-7.05 (m, 12H), 2.17 (s, 6H).

EI-MS: m/z=477 (M⁺).

### Substitution of bis-1,3-(3-methyldiphenylamino)-5-chloro-1,3,5-triazine to prepare 2,4-bis(3-methyldiphenylamino)-6-(3-methoxydiphenylamino)-1,3,5-triazine (3) (Inventive)

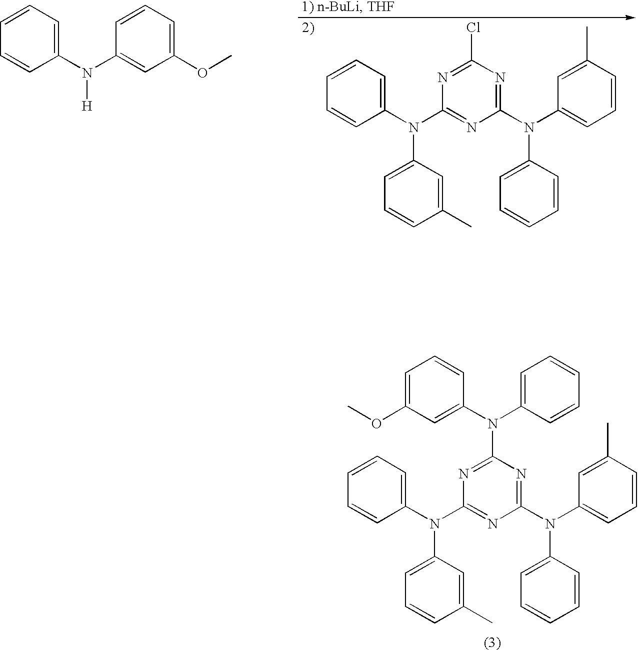

1.19 g (6 mmol) of 3-methoxydiphenylamine are reacted with 4.78 g (5 mmol) of 2,4-bis(3-methyldiphenylamino)-6-chloro-1,3,5-triazine according to method A. The product is purified by means of column chromatography with a hexane/THF eluent mixture (7/1, V/V) to obtain 2.18 g (68%) of 2,4-bis(3-methyldiphenylamino)-6-(3-methoxydiphenylamino)-1,3,5-triazine (3) as a white solid.

¹H NMR (250 MHz, CDCl₃) δ (ppm): 6.98-7.17 (m, 18H), 6.81-6.95 (m, 6H), 6.55-6.76 (m, 3H), 3.63 (s, 3H), 2.17 (s, 6H).

EI-MS: m/z=640 (M⁺).

### Example d

### Trisubstitution of 2,4,6-trichloro-1,3,5-triazine to prepare 2,4,6-tris(3-methoxydiphenylamino)-1,3,5-triazine (4) (Inventive)

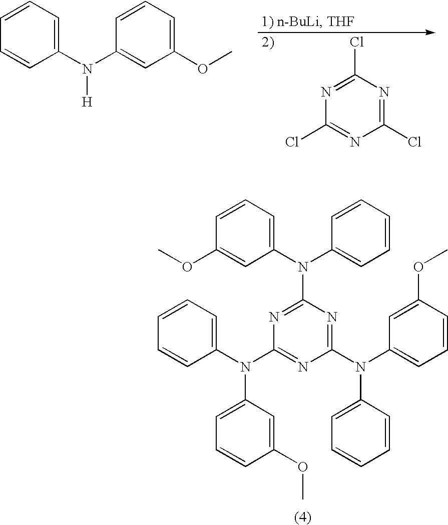

6.97 g (35 mmol) of 3-methoxydiphenylamine are reacted with 1.84 g (10 mmol) of cyanuric chloride according to method A. The product is purified by means of column chromatography with a hexane/THF eluent mixture (10/1, V/V) to obtain 3.43 g (51%) of 2,4,6-tris(3-methoxydiphenylamino)-1,3,5-triazine (4) as a white solid.

¹H NMR (250 MHz, CDCl₃): δ (ppm) 6.95-7.16 (m, 18H), 6.56-6.76 (m, 9H), 3.63 (s, 9H).

EI-MS: m/z=672 (M⁺).

### 2.) Thermal Properties of the Tris(Diphenylamino)Triazine Compounds Prepared According to 1.)

All thermal data reported here were measured by means of differential scanning calorimetry (DSC) on a Perkin-Elmer DSC-7 calorimeter with a heating and cooling rate of 10 K/min under inert gas.

The chemical structural formulae of the individual triazine derivatives are listed below.

### Example e

### Comparative

The unsubstituted 2,4,6-tris(diphenylamino)-1,3,5-triazine (1) (comparative) melts at 308° C. during the first heating phase. During the subsequent cooling phase, the compound crystallizes almost completely at a temperature of 264° C. When the compound is heated again, the amorphous part of the sample recrystallizes at a temperature of 208° C.

Films which are applied by vacuum evaporation or spin-coating crystallize immediately after or during the production.

### Example f

### Comparative

The meta-methyl-substituted (2) (comparative) exhibits a melting point at 175° C. during the first heating phase. During the subsequent cooling phase, the compound crystallizes almost completely in a slow complex process. The crystallization peak extends from 125° C. to 90° C. with several maxima. The most intense maximum is discernible at a temperature of 102° C. The crystallization enthalpy is 24 kJ/mol. During the next heating phase, the amorphous portion of the sample recrystallizes at a temperature of 119° C.

Films which are produced by vacuum evaporation or spin-coating are amorphous over several hours up to one day before a crystallization process sets in.

### Example g

### Inventive

2,4-Bis(3-methyldiphenylamino)-6-(3-methoxydiphenylamino)-1,3,5-triazine (3) (inventive) exhibits a melting point at 153° C. during the first heating phase. During the subsequent cooling phase, the compound solidifies in a glasslike manner. The subsequent heating cycles exhibit a glass transition at a temperature of 39° C. When heating is continued, this leads to recrystallization at 100° C. and melting at 156° C. During cooling at 10 K/min, no crystallization is observed.

Films which are produced by vacuum evaporation or spin-coating are amorphous over the course of two weeks before a crystallization process sets in.

### Example h

### Inventive

The meta-methoxy-substituted 2,4,6-tris(3-methoxydiphenylamino)-1,3,5-triazine (4) (inventive) exhibits a melting point at 167° C. during the first heating phase. In all further heating and cooling cycles, no crystallization or recrystallization is observed. During the heating phase, a glass transition temperature is measured at 37° C.

Films which are produced by vacuum evaporation or spin-coating are amorphous over the course of the entire analysis period (more than 60 days).

TABLE 1
Thermal properties of tris(diphenylamino)triazine compounds of the
general formula (I) according to Examples e) to h)

| | Tₘ | T_{c} | T_{rec} | T_{g} | Crystallization of |
|---|---|---|---|---|---|
| Compound | [° C.]¹⁾ | [° C.]²⁾ | [° C.]³⁾ | [° C.]⁴⁾ | the films |
| 1 (Comparative) | 309 | 265 | 208 | — | immediately |
| 2 (Comparative) | 175 | 102 | 119 | — | 1 day |
| 3 (Inventive) | 153 | — | 100 | 39 | 2 weeks |
| 4 (Inventive) | 168 | — | — | 38 | >60 days |

¹⁾Melting point
²⁾Crystallization temperature
³⁾Recrystallization temperature
⁴⁾Glass transition temperature

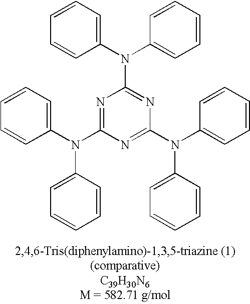

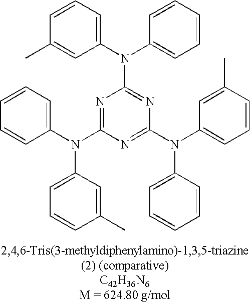

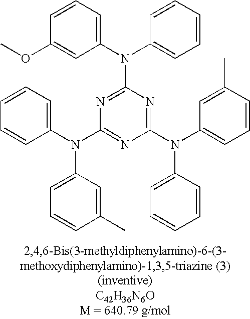

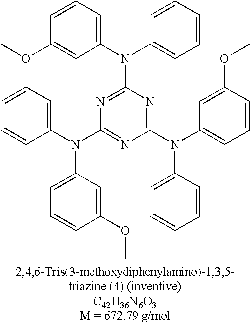

### 3.) Diodes Comprising tris(diphenylamino)triazine Compounds Prepared According to 1

### Example i

### Production of an OLED Comprising 2,4,6-tris(diphenylamino)-1,3,5-triazine (1) as a Matrix Material (Comparative)

The ITO substrate used as the anode is first cleaned in an acetone/isopropanol mixture in an ultrasound bath. To remove possible organic residues, the substrate is cleaned in an O₂ plasma for a further 10 minutes.

Thereafter, the organic materials specified below are applied by vapor deposition to the cleaned substrate at a rate of approx. 0.5-5 nm/min at 10⁻⁶ mbar. The hole conductor and exciton blocker applied to the substrate is N,N′-di(naphth-1-yl)-N,N′-diphenylbenzidine (α-NPD) (C1) with a thickness of 30 nm.

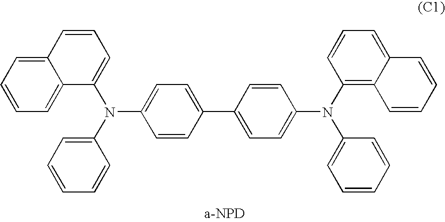

Subsequently, a mixture of 20% by weight of the compound iridium(III) bis[(4,6-difluorophenyl)pyridinato-N,C2′]picolinate (Flrpic) (C2) and 80% by weight of the compound 2,4,6-tris(diphenylamino)-1,3,5-triazine (1) is applied by vapor deposition in a thickness of 40 nm, the former compound functioning as an emitter, the latter as a matrix material.

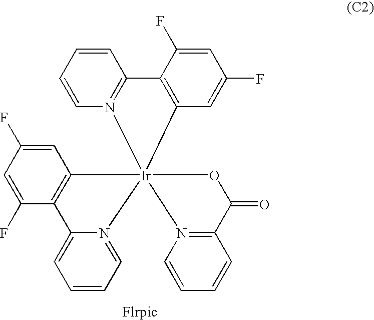

Next, the electron transporter and exciton/hole blocker bis(2-methyl-8-quinolinolato)-4-(phenylphenolato)aluminum(III) (BAlq) (C3) is applied by vapor deposition in a thickness of 30 nm, then a 1 nm-thick lithium fluoride layer and finally a 200 nm-thick aluminum electrode.

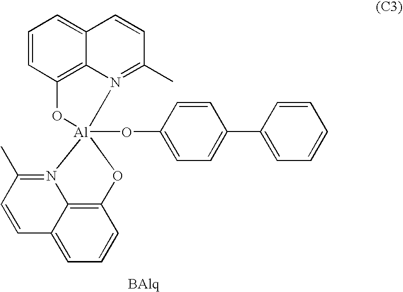

The compounds α-NPD (C1), Flrpic (C2) and BAlq (C3) are commercially available.

To characterize the OLED, electroluminescence spectra are recorded at various currents and voltages. In addition, the current-voltage characteristic is measured in combination with the amount of light emitted with a photometer.

To determine the stability of the OLED with regard to the crystallization tendency, the OLED was stored at room temperature under a nitrogen atmosphere for one day and analyzed again.

For the OLED described, the following electrooptical data are obtained:

| | |
|---|---|
| Emission maximum | n.d. |
| CIE(x, y) | 0.17; 0.32 |
| Photometric efficiency at 10 V | 0.005 cd/A |
| Power efficiency at 10 V | 0.001 lm/W |
| Luminance at 10 V (maximum value) | 1.2 cd/m² |

After one day of storage, the following electrooptical data are obtained for the OLED described:

| | |
|---|---|
| Emission maximum | n.d.* |
| CIE(x, y) | n.d.* |
| Photometric efficiency at a luminance of | n.d.* |
| 100 cd/m² | |
| Luminance | n.d.* |

*As a result of crystallization of the matrix material, the function of the OLED is irreversibly impaired.
(n.d. = not detectable)

The use of 2,4,6-tris(diphenylamino)-1,3,5-triazine (1) with tris(2-phenylpyridine)indium(III) (Ir(ppy)₃), the former compound functioning as a matrix material, the latter as an emitter, in an OLED was described by H. Inomata et al., Chemistry of Materials 2004, 16, 1285. A function of the matrix material in the OLED could not be determined owing to poor film formation properties.

### Example k)

### Production of an OLED Comprising 2,4,6-tris(3-methyldiphenylamino)-1,3,5-triazine (2) as a Matrix Material (Comparative)

The ITO substrate used as the anode is first cleaned in an acetone/isopropanol mixture in an ultrasound bath. To remove possible organic residues, the substrate is cleaned in an O₂ plasma for a further 10 minutes.

Thereafter, the organic materials specified below are applied by vapor deposition to the cleaned substrate at a rate of approx. 0.5-5 nm/min at about 10⁻⁶ mbar. The hole conductor and exciton blocker applied to the substrate is N,N¹-di(naphth-1-yl)-N,N′-diphenylbenzidine (α-NPD) (C1) with a thickness of 30 nm.

Subsequently, a mixture of 20% by weight of the compound indium(III) bis[(4,6-difluorophenyl)pyridinato-N,C21 picolinate (Flrpic) (C2) and 80% by weight of the compound 2,4,6-tris(3-methyldiphenylamino)-1,3,5-triazine (2) is applied by vapor deposition in a thickness of 40 nm, the former compound functioning as an emitter, the latter as a matrix material.

Next, the electron transporter and exciton/hole blocker bis(2-methyl-8-quinolinolato)-4-(phenylphenolato)aluminum(III) (BAlq) (C3) is applied by vapor deposition in a thickness of 30 nm, then a 1 nm-thick lithium fluoride layer and finally a 200 nm-thick aluminum electrode.

To characterize the OLED, electroluminescence spectra are recorded at various currents and voltages. In addition, the current-voltage characteristic is measured in combination with the amount of light emitted with a photometer. To determine the stability of the OLED with regard to the crystallization tendency, the OLED was stored at room temperature under a nitrogen atmosphere for one day and analyzed again.

For the OLED described, the following electrooptical data are obtained:

| | |
|---|---|
| Emission maximum | 470 nm |
| CIE(x, y) | 0.17; 0.34 |
| Photometric efficiency at a luminance of | 2.7 cd/A |
| 100 cd/m² | |
| Power efficiency at a luminance of | 1.2 lm/W |
| 100 cd/m² | |
| Photometric efficiency at a luminance of | 7.3 cd/A |
| 1000 cd/m² | |
| Power efficiency at a luminance of | 2.3 lm/W |
| 1000 cd/m² | |
| Luminance at 10 V | 1000 cd/m² |

After one day of storage, the following electrooptical data are obtained for the OLED described:

| | |
|---|---|
| Emission maximum | n.d.* |
| CIE(x, y) | n.d.* |
| Photometric efficiency at a luminance of | n.d.* |
| 100 cd/m² | |
| Luminance | n.d.* |

*As a result of crystallization of the matrix material, the function of the OLED is irreversibly impaired.
(n.d. = not detectable)

### Example I)

### Production of an OLED Comprising 2,4,6-tris(3-methoxydiphenylamino)-1,3,5-triazine (4) (Inventive) as a Matrix Material

The ITO substrate used as the anode is first cleaned in an acetone/isopropanol mixture in an ultrasound bath. To remove possible organic residues, the substrate is cleaned in an O₂ plasma for a further 10 minutes.

Thereafter, the organic materials specified below are applied by vapor deposition to the cleaned substrate at a rate of approx. 0.5-5 nm/min at about 10⁻⁶ mbar. The hole conductor and exciton blocker applied to the substrate is N,N′-di(naphth-1-yl)-N,N′-diphenylbenzidine (α-NPD) (C1) with a thickness of 30 nm.

Subsequently, a mixture of 20% by weight of the compound indium(III) bis[(4,6-difluorophenyl)pyridinato-N,C2′]picolinate (Flrpic) (C2) and 80% by weight of the compound 2,4,6-tris(3-methoxydiphenylamino)-1,3,5-triazine (4) (inventive) is applied by vapor deposition in a thickness of 40 nm, the former compound functioning as an emitter, the latter as a matrix material.

Next, the electron transporter and exciton/hole blocker bis(2-methyl-8-quinolinolato)-4-(phenylphenolato)aluminum(III) (BAlq) (C3) is applied by vapor deposition in a thickness of 30 nm, then a 1 nm-thick lithium fluoride layer and finally a 200 nm-thick aluminum electrode.

To characterize the OLED, electroluminescence spectra are recorded at various currents and voltages. In addition, the current-voltage characteristic is measured in combination with the amount of light emitted with a photometer.

To determine the stability of the OLED with regard to the crystallization tendency, the OLED was stored at room temperature under a nitrogen atmosphere for one day and analyzed again.

For the OLED described, the following electrooptical data are obtained:

| | |
|---|---|
| Emission maximum | 470 nm |
| CIE(x, y) | 0.17; 0.34 |
| Photometric efficiency at a luminance of | 12.2 cd/A |
| 100 cd/m² | |
| Power efficiency at a luminance of | 5.0 lm/W |
| 100 cd/m² | |
| Photometric efficiency at a luminance of | 9.3 cd/A |
| 1000 cd/m² | |
| Power efficiency at a luminance of | 2.7 lm/W |
| 1000 cd/m² | |
| Luminance at 10 V | 1000 cd/m² |

After one day of storage, the following electrooptical data are obtained for the OLED described:

| | |
|---|---|
| Emission maximum | 470 nm |
| CIE(x, y) | 0.17; 0.34 |
| Photometric efficiency at a luminance of | 8.5 cd/A |
| 1000 cd/m² | |
| Luminance at 17 V | 1000 cd/m² |

1. An organic light-emitting diode comprising at least one tris(diphenylamino)triazine compound of the general formula (I) 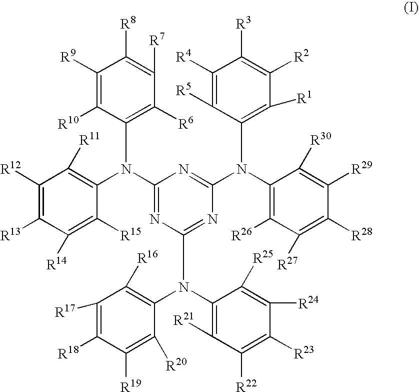
in which the R¹ to R³⁰ radicals are each independently defined as follows:
hydrogen, alkyl, cycloalkyl, heterocycloalkyl, aryl, heteroaryl, OH, O-alkyl, O-aryl, O-heteroaryl, SH, S-alkyl, S-aryl, halogen, pseudohalogen, amino or further substituents with donor or acceptor action,
or
a radical of the formula (I) 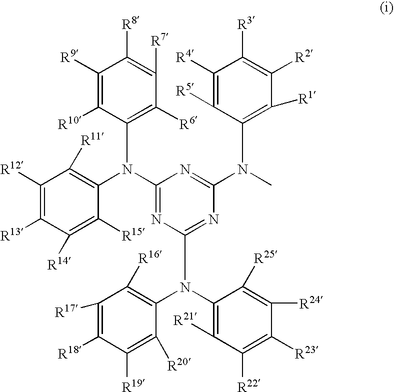
in which the R^{1′}, R^{2′}, R^{3′}, R^{4′}, R^{5′}, R^{6′}, R^{7′}, R^{8′}, R^{9′}, R^{10′}, R^{11′}, R^{12′}, R^{13′}, R^{14′}, R^{15′}, R^{16′}, R^{17′}, R^{18′}, R^{19′}, R^{20′}, R^{21′}, R^{22′}, R^{23′}, R^{24′}, and R^{25′} radicals are each independently as defined for the R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴ and R²⁵ radicals;
with the condition that at least one of the radicals of at least one of the R², R⁴, R⁷, R⁹, R¹², R¹⁴, R¹⁷, R¹⁹, R²², R²⁴, R²⁷ or R²⁹ radicals is O-alkyl or O-aryl.

2. The organic light-emitting diode according to claim 1, wherein the R¹ to R³⁰ and R^{1′} to R^{25′} radicals are each independently hydrogen, alkyl, cycloalkyl, O-alkyl, O-aryl, aryl, SH, S-alkyl, S-aryl, halogen, pseudohalogen or amino, preferably hydrogen, C₁- to C₈-alkyl, especially methyl, ethyl, n-propyl, i-propyl, n-butyl, i-butyl, sec-butyl or tert-butyl, or halogen-substituted C₁- to C₈-alkyl, e.g. CF₃, aryl, especially phenyl, halogen, especially F or Cl, pseudohalogen, especially CN, O-alkyl, especially O—C₁- to C₈-alkyl, O-aryl, especially O—C₆-aryl, or SiR³¹R³²R³³ where the R³¹, R³² and R³³ radicals are each C₁-C₆-alkyl, e.g. methyl, ethyl or i-propyl, or substituted or unsubstituted phenyl, especially SiMe₃, more preferably methyl, ethyl, F, CN, CF₃, SiMe₃ or O-methyl.

3. The organic light-emitting diode according to claim 1 or 2, wherein the compound of the formula (I) has 1, 2, 3, 4, 5 or 60-alkyl and/or O-aryl radicals.

4. The organic light-emitting diode according to any of claims 1 to 3, wherein the R¹, R⁵, R⁶, R¹⁰, R¹¹, R¹⁵, R¹⁶, R²⁰, R²¹, R²⁵, R²⁶ and R³⁰ radicals are each hydrogen.

5. The organic light-emitting diode according to any of claims 1 to 4, wherein the compounds of the formula (I) have the formulae (Ia), (Ib), (Ic), (Id), (Ie) or (If): 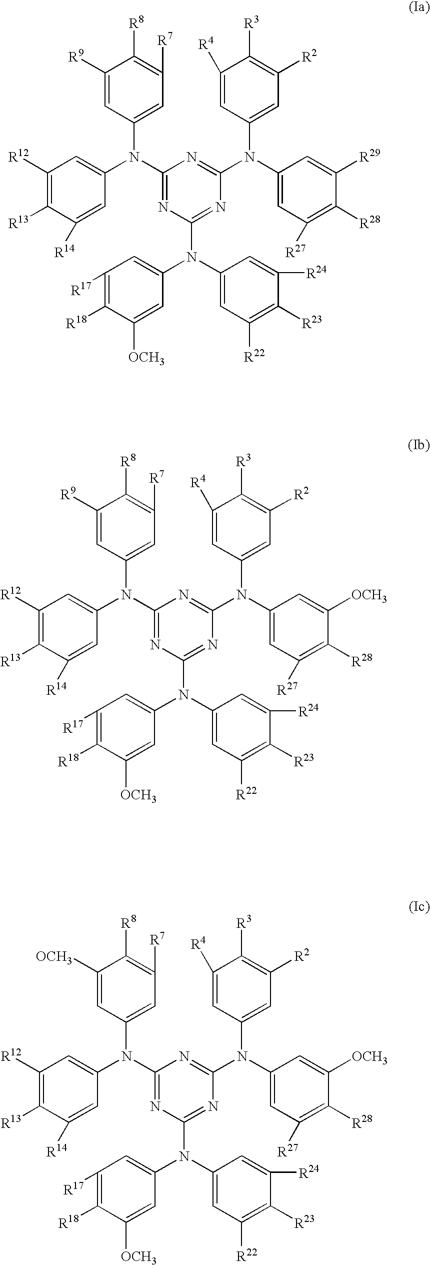 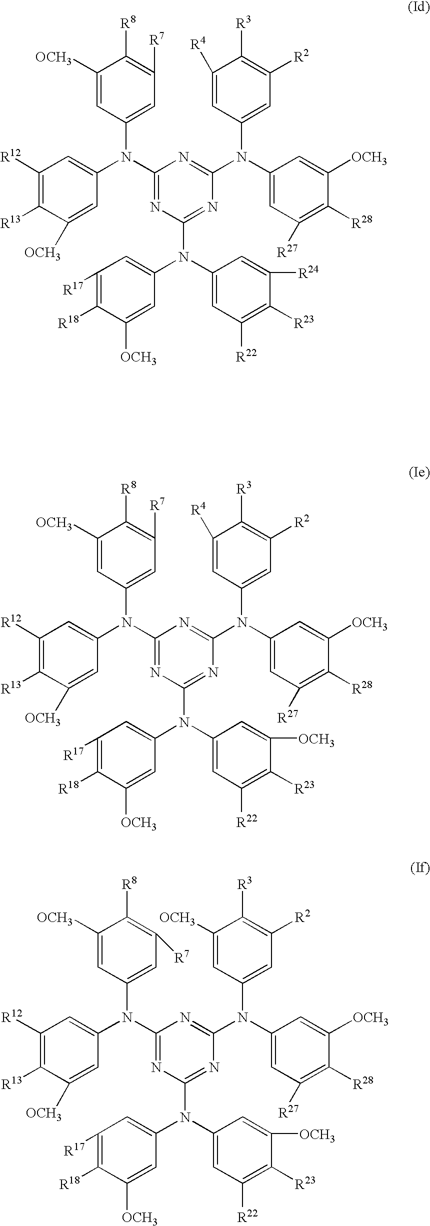
in which:
R³, R⁸, R¹³, R¹⁸, R²³ and R²⁸ are each independently hydrogen, methyl, ethyl, F, CF₃, SiMe₃ or CN, and
R², R⁴, R⁷, R⁹, R¹², R¹⁴, R¹⁷, R²², R²⁴, R²⁷ and R²⁹—if they are not OCH₃— are each independently hydrogen or C₁- to C₄-alkyl.

6. The organic light-emitting diode according to any of claims 1 to 5, wherein the compounds of the formula (I) are used as a matrix material and/or hole/exciton blocker material and/or electron/exciton blocker material and/or hole injection material and/or electron injection material and/or hole conductor material and/or electron conductor material.

7. The organic light-emitting diode according to any of claims 1 to 6, wherein the compounds of the formula (I) are used together with at least one triplet emitter in the organic light-emitting diode.

8. The use of compounds of the formula (I) according to any of claims 1 to 5 in organic light-emitting diodes.

9. A light-emitting layer comprising at least one compound of the formula (I) according to any of claims 1 to 5, preferably together with at least one triplet emitter.

10. A blocking layer for electrons, blocking layer for holes, hole injection layer, electron injection layer, hole conductor layer and/or electron conductor layer comprising at least one compound of the formula (I) according to any of claims 1 to 5.

11. An organic light-emitting diode comprising at least one light-emitting layer according to claim 10 and/or at least one blocking layer for electrons, blocking layer for holes, hole injection layer, electron injection layer, hole conductor layer and/or electron conductor layer according to claim 10.

12. A device selected from the group consisting of stationary visual display units such as visual display units of computers, televisions, visual display units in printers, kitchen appliances and advertising panels, illuminations, information panels, and mobile visual display units such as visual display units in cellphones, laptops, digital cameras, vehicles, and also destination displays on buses and trains and illumination units comprising at least one organic light-emitting diode according to any of claims 1 to 7 or 11.
